(19) United States
(12) Patent Application Publication
(10) Pub. No.: US 2015/0162929 A1
(43) Pub. Date: Jun. 11, 2015

(54) ANALOG-TO-DIGITAL CONVERTER AND IMAGE SENSOR

(71) Applicant: KABUSHIKI KAISHA TOSHIBA, Minato-ku (JP)

(72) Inventors: Yasuhiro SHINOZUKA, Fuchu (JP); Masanori FURUTA, Odawara (JP); Kei SHIRAISHI, Fuchu (JP)

(73) Assignee: KABUSHIKI KAISHA TOSHIBA, Minato-ku (JP)

(21) Appl. No.: 14/561,883

(22) Filed: Dec. 5, 2014

(30) Foreign Application Priority Data
Dec. 9, 2013 (JP) 2013-254407

(51) Int. Cl. H03M 1/12; H04N 5/372; H03M 1/18; H04N 5/369; H03M 1/34; H04N 5/378; H04N 5/3745

(52) U.S. Cl. CPC H03M 1/1245; H04N 5/378; H04N 5/372; H04N 5/37455; H04N 5/3698; H03M 1/34; H03M 1/186

(57) ABSTRACT

An analog-to-digital converter has a comparator to compare, within a predetermined period, an input signal with a ramp signal or with a triangle wave signal, a first counter to count up or down in accordance with a logic of a signal that indicates a comparison result of the comparator within the predetermined period, a count value storage to sequentially store count values of the first counter whenever the logic of the signal that indicates a comparison result of the comparator changes within the predetermined period, a second counter to count the number of times the logic of the signal that indicates a comparison result of the comparator changes, and an arithmetic module to output a value obtained by adding up the count values stored in the count value storage and dividing the added-up value by a count value of the second counter.

### CROSS REFERENCE TO RELATED APPLICATIONS

This application is based upon and claims the benefit of priority from the prior Japanese Patent Application No. 2013-254407, filed on Dec. 9, 2013, the entire contents of which are incorporated herein by reference.

### FIELD

Embodiments of the present invention relate to an integral analog-to-digital converter and an image sensor provided with the analog-to-digital converter.

### BACKGROUND

An integral analog-to-digital converter that improves an analog-to-digital conversion accuracy by averaging results of a plurality of times of signal level comparison between an input signal and a reference signal has been proposed.

This type of known integral analog-to-digital converter has a problem in that, when an input signal has small noise, the noise cannot be effectively reduced by a plurality of times of sampling, and quantization noise of an A/D converter also cannot be reduced. In other words, a reference signal is generated by varying stepwise the output of an integrator by a specific voltage for each clock. Therefore, when an input signal has small noise, the same digital value is obtained even by a plurality of times of sampling, which results in the same S/N ratio as in the case of one-time sampling.

When an input signal has a higher level, there is a problem of longer A/D conversion time. In other words, when an input signal has a higher level, it takes time for the output of an integrator and an input signal to have the same level at the first time of sampling. Therefore, when the number of times of sampling is fixed, the A/D conversion time varies depending on the input signal.

### BRIEF DESCRIPTION OF THE DRAWINGS

FIG. 1 is a block diagram schematically showing the configuration of an analog-to-digital converter 1 according to a first embodiment;

FIG. 2 is a chart of signal waveforms of the analog-to-digital converter 1 of FIG. 1;

FIG. 3 is a chart showing a simulation result of an operation of the analog-to-digital converter 1 of FIG. 1 with a C-language program;

FIG. 4 is a circuit diagram showing a first example of the internal configuration of a reference signal generator 2;

FIG. 5 is a circuit diagram showing a second example of the internal configuration of the reference signal generator 2;

FIG. 6 is a block diagram showing the main part of an analog-to-digital converter 1 according to a second embodiment;

FIG. 7 is a circuit diagram showing an example of the internal configuration of a triangle wave generator 31;

FIG. 8 is a block diagram showing the main part of an analog-to-digital converter 1 according to a third embodiment;

FIG. 9 is a circuit diagram showing an example of the internal configuration of a signal synthesizer 41;

FIG. 10 is a block diagram schematically showing the configuration of an image sensor 50 having the analog-to-digital converter 1 of any one of the first to third embodiments; and

FIG. 11 is a plan view of an image sensor 50 having built-in CCDs.

### DETAILED DESCRIPTION

According to one embodiment, an analog-to-digital converter has:

a comparator to compare, within a predetermined period, an input signal with a ramp signal whose signal level monotonically increases or monotonically decreases with time, or with a triangle wave signal that alternately repeats monotonic increase and monotonic decrease with time;

a first counter to count up or down in accordance with a logic of a signal that indicates a comparison result of the comparator within the predetermined period;

a count value storage to sequentially store count values of the first counter whenever the logic of the signal that indicates a comparison result of the comparator changes within the predetermined period;

a second counter to count the number of times the logic of the signal that indicates a comparison result of the comparator changes; and

an arithmetic module to output a value obtained by adding up the count values stored in the count value storage and dividing the added-up value by a count value of the second counter, as an analog-to-digital conversion value of the input signal.

Embodiments will now be explained with reference to the accompanying drawings.

### First Embodiment

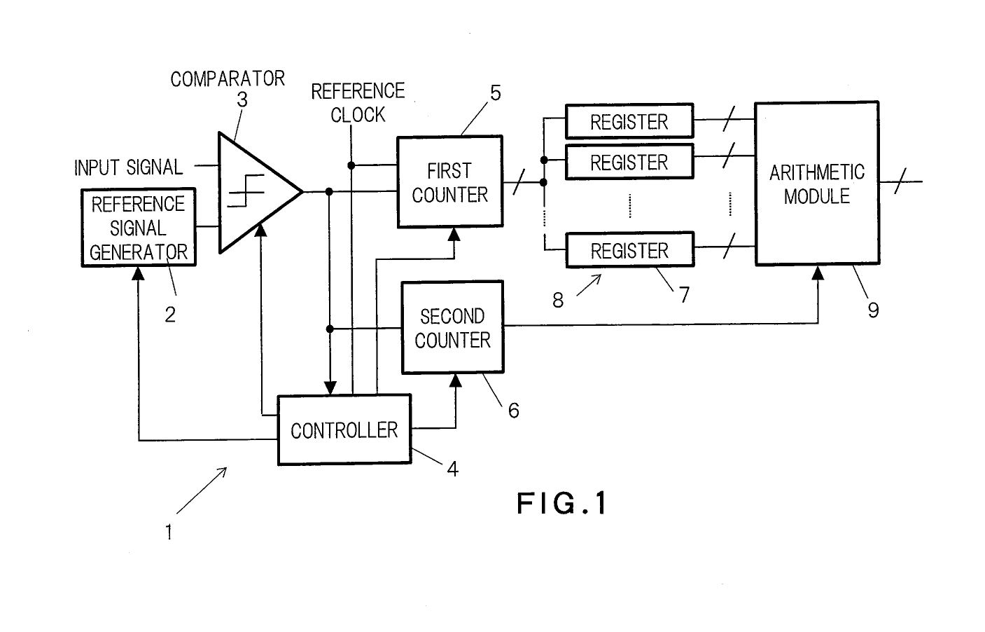

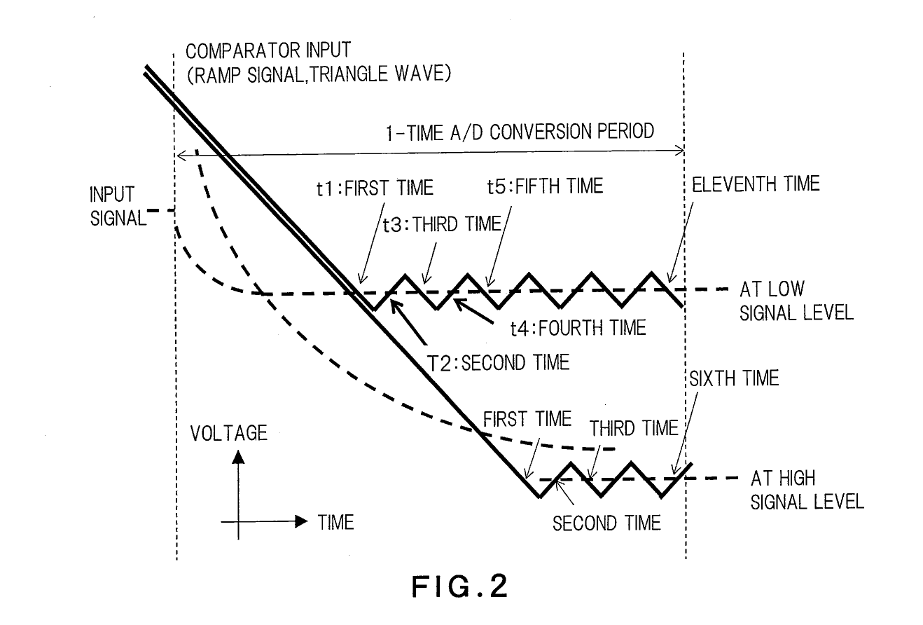

FIG. 1 is a block diagram schematically showing the configuration of an analog-to-digital converter 1 according to a first embodiment. FIG. 2 is a chart of signal waveforms of the analog-to-digital converter 1 of FIG. 1. The analog-to-digital converter 1 of FIG. 1 is provided with a reference signal generator 2, a comparator 3, a controller 4, a first counter 5, a second counter 6, a count value storage 8 having a plurality of registers 7, and an arithmetic module 9.

The reference signal generator 2 generates a ramp signal or a triangle wave signal based on a control signal from the controller 4. A ramp signal is a signal whose signal level monotonically increases or monotonically decreases with time. A triangle wave signal is a signal that alternately repeats monotonic increase and monotonic decrease with time.

In more detail, as shown in FIG. 2, the reference signal generator 2 generates a ramp signal in the beginning of an A/D conversion process to an input signal. The reference signal generator 2 generates a triangle wave signal at and after time t1 at which the comparator 3 detects that the signal level of the input signal is lower than the signal level of the ramp signal.

The comparator 3 compares the ramp signal or triangle wave signal generated by the reference signal generator 2 and an input signal to output a signal indicating a comparison result.

The controller 4 generates a control signal based on the signal indicating a comparison result of the comparator 3. For example, the controller 4 generates a low-level control signal when the signal level of the input signal is equal to or higher than the signal level of the ramp signal or triangle wave signal. However, when the signal level of the input signal is lower than the signal level of the ramp signal or triangle wave signal, the controller 4 generates a high-level control signal. The control signal is supplied to the reference signal generator 2, the first counter 5 and the second counter 6.

Once the reference signal generator 2 switches its output signal from a ramp signal to a triangle wave signal, the reference signal generator 2 switches the triangle wave signal between a monotonic increase tendency and monotonic decrease tendency whenever the logic of the signal indicating a comparison result of the comparator 3 changes. In this case, the reference signal generator 2 may switch the triangle wave signal at the edge of a reference clock signal that comes just after the change in the logic of the signal indicating a comparison result of the comparator 3. Instead, the reference signal generator 2 may switch the triangle wave signal after the passage of several cycles of a reference clock signal after the change in the logic of the signal indicating a comparison result of the comparator 3.

In the example of FIG. 2, the reference signal generator 2 switches a ramp signal to a triangle wave signal at and after time t1. When the triangle wave signal crosses with an input signal for the second time (time t2), the reference signal generator 2 switches the triangle wave signal so as to have the monotonic decrease tendency. After that, when the triangle wave signal crosses with the input signal for the third time (time t3), the reference signal generator 2 switches the triangle wave signal so as to have the monotonic increase tendency. Thereafter, whenever the triangle wave signal crosses the input signal, the reference signal generator 2 alternately switches the signal slope of the triangle wave signal.

The first counter 5 and the second counter 6 operate in synchronism with a reference clock signal. The first counter 5 is an up/down counter that performs count-up or count-down in accordance with the logic of a signal that indicates a comparison result of the comparator 3, within a specific period of time. For example, within a period in which the signal level of an input signal is equal to or higher than the signal level of a ramp signal or triangle wave signal, the first counter 5 continuously performs count-up in synchronism with a reference clock signal. However, within a period in which the signal level of the input signal is lower than the signal level of the ramp signal or triangle wave signal, the first counter 5 continuously performs count-down in synchronism with the reference clock signal. Whenever the signal levels cross each other between the input signal and the ramp signal or triangle wave signal, a count value of the first counter 5 is stored in one of registers 7 in the count value storage 8, thereby counted values being sequentially stored in different registers 7. Accordingly, A/D-converted values almost identical with the signal level of the input signal are stored in the respective registers 7.

A specific period for the first counter 5 to perform a counting operation is always constant irrespective of the signal level of an input signal, that is an A/D conversion period required for A/D conversion of one input signal. The A/D conversion period has been previously set to a specific period of time.

The second counter 6 counts the number of times the logic of a signal indicating a comparison result of the comparator 3 changes within a specific period of time, that is, the A/D conversion period. For example, in the example of FIG. 2, while an input signal has a low signal level, the logic of a signal indicating a comparison result of the comparator 3 changes eleven times within one A/D conversion period, hence the count value of the second counter 6 becomes eleven. However, while the input signal has a high signal level, the count value of the second counter 6 becomes six.

The arithmetic module 9 outputs a value, as an A/D conversion value of the input signal, obtained by adding up all count values stored in the registers 7 in the count value storage 8 and dividing the added-up value by a count value of the second counter 6.

In this embodiment, the number of times of sampling one input signal with a triangle wave signal within an A/D conversion period is not decided to any particular number of times. This is because the noise on a small input signal becomes problematic when widening the dynamic range. When an input signal has a high signal level, the S/N ratio of the input signal is so high that the S/N ratio is not so improved even when the input signal is sampled with a triangle wave signal many times and the sampled values are averaged by being divided by the sampling times. For this reason, in this embodiment, as shown in FIG. 2, for a large input signal, the period for sampling the input signal with a triangle wave signal is set to a short period.

In contrast, when an input signal has a low signal level, the S/N ratio of the input signal is low. Thus, in this embodiment, as shown in FIG. 2, the input signal is sampled with a triangle wave signal as many times as possible and sampled values are averaged by being divided by the sampling times, thereby improving the S/N ratio.

Moreover, in this embodiment, an A/D conversion process period is constant for each input signal, irrespective of the signal level of the input signal. Therefore, according to this embodiment, the dynamic range can be widened without lengthening the A/D conversion process period.

As described above, in this embodiment, since the number of times of sampling is changed depending on the signal level of an input signal, the arithmetic module 9 is required to perform an averaging process in accordance with the sampling times.

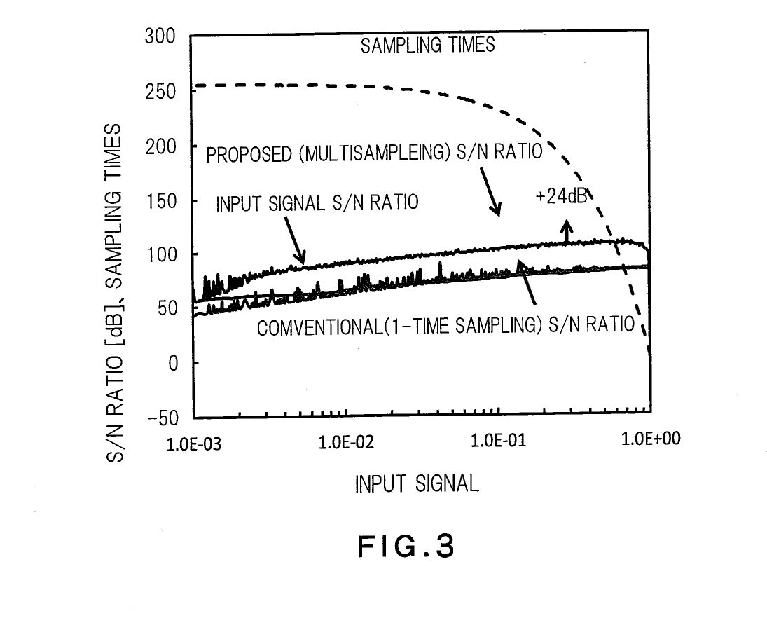

FIG. 3 is a chart showing a simulation result of an operation of the analog-to-digital converter 1 of FIG. 1 with a C-language program. In FIG. 3, the abscissa represents an input signal varying in the range of 10⁻³ to 1 and the ordinate represents an S/N ratio of the input signal, with the S/N ratio and sampling times of the analog-to-digital converter 1 of FIG. 1, and the S/N ratio of an analog-to-digital converter 1 of a comparative example. The analog-to-digital converter 1 of the comparative example acquires an A/D conversion value at a moment whenever an input signal crosses a ramp signal.

The simulation shown in FIG. 3 was carried out with the conditions that the shot noise contained in an input signal was 10⁻⁴×√ (input signal), the thermal noise independent of the input signal was 10⁻⁶ , the resolution of the analog-to-digital converters 1 was 16-bit, and a triangle wave rose up and fell down at a 128-clock interval.

As understood from FIG. 3, the number of times of sampling increases as the input signal becomes smaller, which results in 24-dB increase in S/N ratio compared to the comparative example.

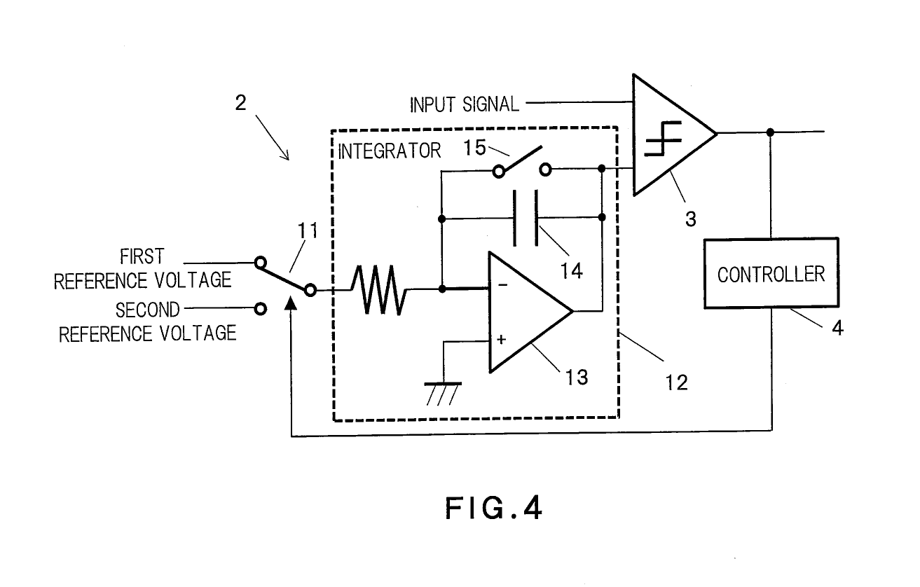

FIG. 4 is a circuit diagram of a first example of the internal configuration of the reference signal generator 2. The reference signal generator 2 of FIG. 4 has a reference voltage selector 11 and an integrator 12. The reference voltage selector 11 selects a first reference voltage or a second reference voltage based on a control signal. The first and second reference voltages are both DC voltages. The integrator 12 performs an integration process to monotonically increase or monotonically decrease with time the first or second reference voltage selected by the reference voltage selector 11 to generate a ramp signal or a triangle wave signal. The ramp signal or triangle wave signal generated by the integrator 12 is input to the second terminal of the comparator 3. Accordingly, the comparator 3 compares an input signal input to the first terminal and the ramp signal or triangle wave signal input to the second terminal.

The integrator 12 has an operational amplifier 13, a capacitor 14, a switch 15, and an impedance element 16. The operational amplifier 13 has a grounded non-inverting input terminal and an inverting input terminal connected to the reference voltage selector 11 through the impedance element 16. The capacitor 14 and the switch 15 are connected in parallel between the inverting input terminal and an output terminal of the comparator 3.

The reference voltage selector 11 selects the first reference voltage and turns off the switch 15 to charge the capacitor 14, thereby setting the second input terminal of the comparator 3 to an initial voltage of a ramp signal. Thereafter, the reference voltage selector 11 turns on the switch 15 to discharge the capacitor 14, which causes gradual decrease in the voltage at the second input terminal, that is, the ramp signal.

When the signal levels cross each other between the input signal and the ramp signal, the reference voltage selector 11 selects the second reference voltage and turns off the switch 15. From this moment, a triangle wave signal is input to the second input terminal of the comparator 3, which causes charging the capacitor 14 again to gradually increase the voltage at the second input terminal of the comparator 3. When the signal levels cross each other between the input signal and the ramp signal, the reference voltage selector 11 turns on the switch 15 again to discharge the capacitor 14. This gradually decreases the voltage at the second input terminal, that is, the triangle wave signal. By repeating this operation, the triangle wave signal is input to the second input terminal.

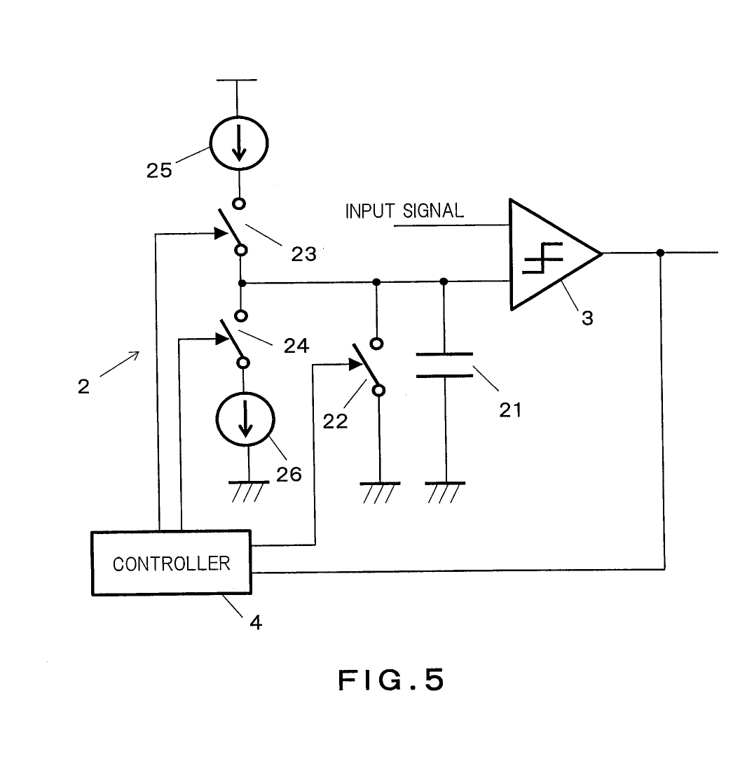

FIG. 5 is a circuit diagram of a second example of the internal configuration of the reference signal generator 2. The reference signal generator 2 of FIG. 5 has a capacitor 21, a first switch 22, a second switch 23, a third switch 24, a first current source 25, and a second current source 26.

The capacitor 21 and the first switch 22 are connected in parallel between the second input terminal of the comparator 3 and a ground node. The first current source 25, the second switch 23, the third switch 24 and the second current source 26 are connected in series between a power supply node and a ground node. The second input terminal of the comparator 3 is connected to a connection node of the second switch 23 and the third switch 24.

Firstly, the second switch 23 is turned on while the first switch 22 and the third switch 24 are turned off to make a current from the first current source 25 flow to the capacitor 21 to charge the capacitor 21, thereby setting the second input terminal to an initial voltage of a ramp signal. Thereafter, the first switch 22 is turned on while the second switch 23 and the third switch 24 are turned off to discharge the capacitor 21, which results in a gradual decrease in the level of the ramp signal.

When the signal levels cross each other between an input signal and the ramp signal, the second switch 23 is turned on again while the first switch 22 and the third switch 24 are turned off to charge the capacitor 21. Thereafter, the second switch 23 and the third switch 24 are alternately turned on and off to input a triangle wave signal to the second input terminal.

As described above, in the first embodiment, the count value of the first counter 5 is increased or decreased according to whether the levels of an input signal and a ramp or triangle wave signal is higher or lower than the other. Whenever the signal levels cross each other between the input signal and the ramp signal or triangle wave signal, the count value of the first counter 5 is stored in the registers 7 in the count value storage 8 and the number of times of crossing is counted by the second counter 6. When a predetermined A/D conversion period is completed, the arithmetic module 9 adds up count values stored in the registers 7 and divides the added value by the count value of the second counter 6, thereby the count values being averaged to be a final A/D conversion value. In this way, even for an input signal having a low level, A/D conversion can be performed accurately with no decrease in resolution.

Moreover, in the first embodiment, the A/D conversion period is constant irrespective of the input signal level, and hence A/D conversion can be performed in a short time even if the input signal varies largely.

### Second Embodiment

In a second embodiment which will be explained below, a ramp signal is externally input to an analog-to-digital converter 1 while a triangle wave signal is generated inside the analog-to-digital converter 1.

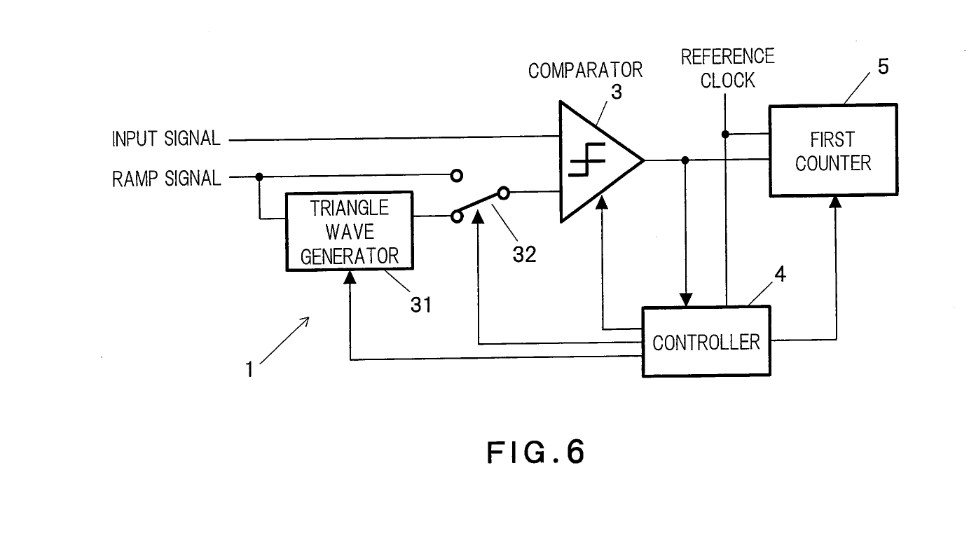

FIG. 6 is a block diagram showing the main part of an analog-to-digital converter 1 according to the second embodiment. The difference between the analog-to-digital converters 1 of FIG. 6 and FIG. 1 is the internal configuration of the reference signal generator 2. The reference signal generator 2 of FIG. 6 has a triangle wave generator 31 and a reference signal switch 32.

A ramp signal is input to the triangle wave generator 31 from the outside of the analog-to-digital converter 1. The triangle wave generator 31 generates a triangle wave signal by using the ramp signal.

Based on the logic of a control signal from the controller 4, the reference signal switch 32 selects either the ramp signal or the triangle wave signal and supplies the selected signal to the second input terminal of the comparator 3. In more detail, the reference signal switch 32 selects the ramp signal just after the start of A/D conversion and then selects the triangle wave signal after the signal levels cross each other between the input signal and the ramp signal.

Although omitted from FIG. 6, there are a second counter 6, a count value storage 8 and an arithmetic module 9 configured in the same way as FIG. 1.

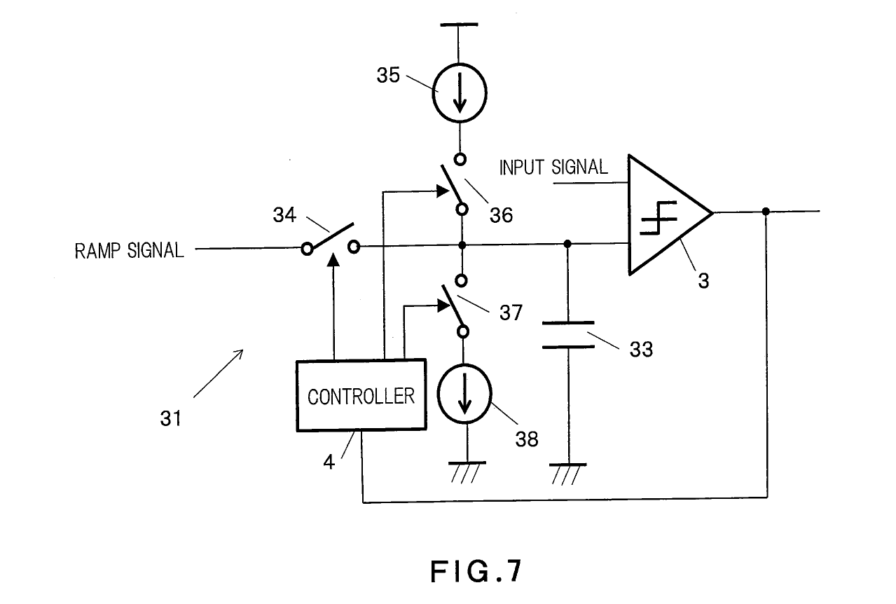

FIG. 7 is a circuit diagram showing an example of the internal configuration of the triangle wave generator 31. The triangle wave generator 31 of FIG. 7 has a capacitor 33 connected between the second input terminal of the comparator 3 and a ground node, a first switch 34 connected between the input terminal of the triangle wave generator 31 and the second input terminal, a first current source 35 connected in series between a power supply node and a ground node, a second switch 36, a third switch 37, and a second current source 38.

Firstly, the first switch 34 is turned on while the second switch 36 and the third switch 37 are turned off to supply a ramp signal to the second input terminal of the comparator 3, which results in that the capacitor 33 holds charges in accordance with the level of the ramp signal.

The first switch 34 is turned off when the signal levels cross each other between an input signal and the ramp signal. Thereafter, the second switch 36 and the third switch 37 are alternately turned on to charge and discharge the capacitor 33, thereby a triangle wave signal being input to the second input terminal.

As described above, in the second embodiment, a ramp signal is generated outside the analog-to-digital converter 1 and input thereto. Since there is no need to generate a ramp signal inside the analog-to-digital converter 1, the internal configuration of the reference signal generator 2 can be simplified compared to the first embodiment.

### Third Embodiment

In a third embodiment which will be explained below, a ramp signal and a triangle wave signal are generated outside an analog-to-digital converter 1.

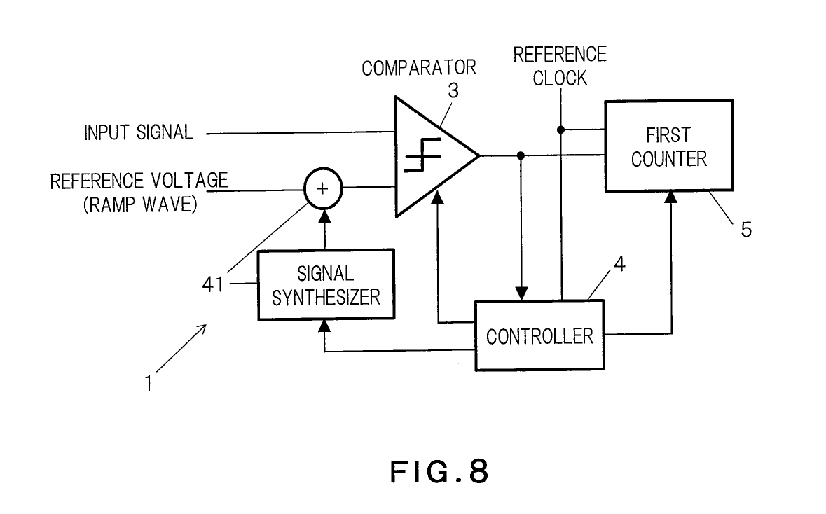

FIG. 8 is a block diagram showing the main part of an analog-to-digital converter 1 according to the third embodiment. Although omitted from FIG. 8, there are a second counter 6, a count value storage 8 and an arithmetic module 9 configured in the same way as FIG. 1.

The analog-to-digital converter 1 of FIG. 8 has a signal synthesizer 41 that generates a signal to be supplied to the second input terminal of a comparator 3 based on an externally generated ramp signal and triangle wave signal.

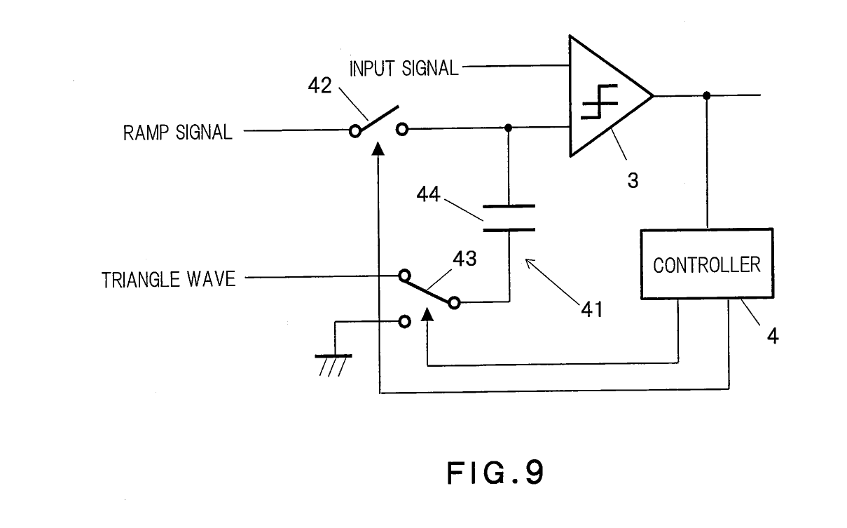

FIG. 9 is a circuit diagram showing an example of the internal configuration of the signal synthesizer 41. The signal synthesizer 41 of FIG. 9 has a first switch 42, a second switch 43, and a capacitor 44.

The first switch 42 is switched to input a ramp signal to the second input terminal of the comparator 3 or not. One end of the capacitor 44 is connected to the second input terminal capacitor 44 of the comparator 3. The other end of the capacitor 44 is connected to the second switch 43. The second switch 43 is switched to input a triangle wave signal to the other end of the capacitor 44 or ground the other end of the capacitor 44.

Just after the start of an A/D conversion process, the first switch 42 is turned on to input a ramp signal to the second input terminal of the comparator 3 and the second switch 43 is switched to set the other end of the capacitor 44 to a ground level. In this way, the capacitor 44 is charged to the ramp signal level.

When the signal levels cross each other between an input signal and the ramp signal, the first switch 42 is turned off and the second switch 43 is switched to the triangle wave signal side. In this way, a triangle wave signal is input to the other end of the capacitor 44, so that the triangle wave signal is supplied to the second input terminal of the comparator 3, with an offset voltage being held by the capacitor 44.

As described above, in the third embodiment, both of the ramp signal and triangle wave signal are supplied from the outside of the analog-to-digital converter 1. Therefore, there is no need to generate the ramp signal and triangle wave signal inside the analog-to-digital converter 1. Accordingly, the circuit configuration of the analog-to-digital converter 1 can be simplified and scaled down to decrease power consumption.

### Fourth Embodiment

The analog-to-digital converters 1 explained in the above first to third embodiments can be built in an image sensor.

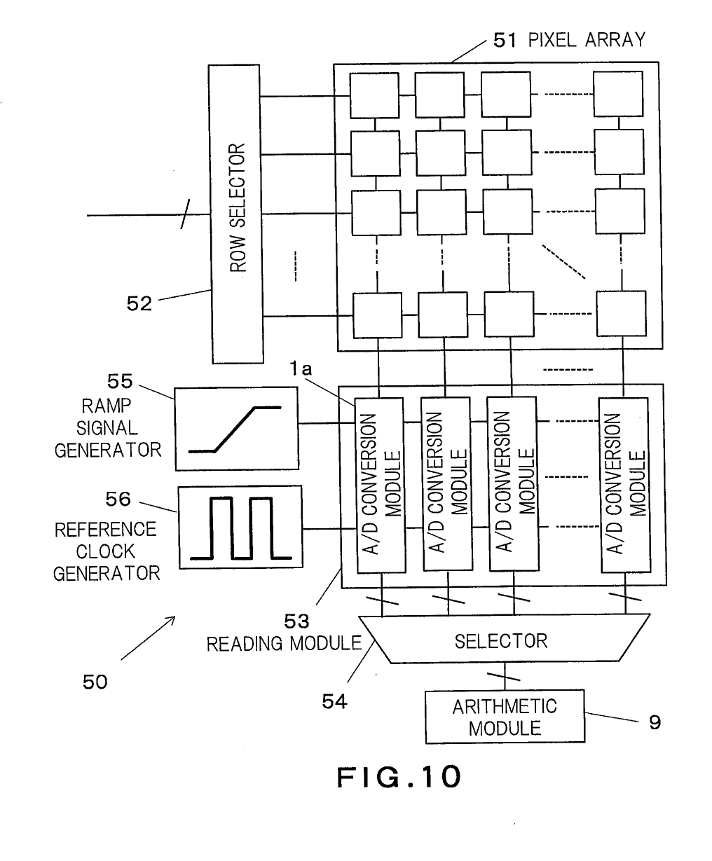

FIG. 10 is a block diagram of schematically showing the configuration of an image sensor 50 having the analog-to-digital converter 1 of any one of the first to third embodiments. The image sensor 50 of FIG. 10 is an CMOS sensor and provided with a pixel array 51, a row selector 52, a reading module 53, a selector 54, an arithmetic module 9, a ramp signal generator 55 and a reference clock generator 56.

The pixel array 51 has a plurality of CMOS sensors arranged in row and column directions. From among the CMOS sensors, the row selector 52 selects a plurality of CMOS sensors aligned in a specific row.

The reading module 53 has a plurality of analog-to-digital conversion modules 1a for the number of CMOS sensors aligned in a column direction in the pixel array 51. These analog-to-digital conversion modules 1a correspond to the analog-to-digital converter 1 of any one of the first to third embodiments, from which the arithmetic module 9 is omitted. The reason for omitting the arithmetic module 9 is that, even if a plurality of arithmetic modules 9 are provided, the arithmetic modules 9 perform the same averaging process mentioned above, and hence there is no need to provide a plurality of identical circuits.

The ramp signal generator 55 has the identical internal configuration for the analog-to-digital converters 1a, and hence can be used for all of the analog-to-digital converters 1a. Thus, the ramp signal generator 55 is not contained in the analog-to-digital converters 1a of FIG. 10 but provided separately from the reading module 53.

The reference clock generator 56 generates clock signals for operating the first counter 5 and the second counter 6 in each analog-to-digital converter 1a.

The selector 54 selects one of output signals of the analog-to-digital converters 1a and supplies the selected signal to the arithmetic module 9. The signal from the selected analog-to-digital converter 1a and supplied to the arithmetic module 9 has the count values of the first counter 5 and the second counter 6, that have been stored in the registers 7 of the count value storage 8.

The arithmetic module 9 uses an A/D conversion result of the analog-to-digital converter 1a selected by the selector 54 to generate a final averaged A/D conversion value. The selector 54 sequentially selects the output signals of the analog-to-digital converters 1a. Therefore, the arithmetic module 9 sequentially generates A/D conversion values of the analog-to-digital converters 1a.

FIG. 10 shows an example in which the ramp signal generator 55 is provided outside the analog-to-digital converters 1a whereas the triangle wave signal generator is provided inside each analog-to-digital converter 1a. However, the triangle wave signal generator may also be provided outside the analog-to-digital converters 1a. Moreover, conversely, if scaling up the circuit causes no problems, the ramp signal generator 55 may be provided inside each analog-to-digital converter 1a.

As described above, the analog-to-digital converter 1 of each of the first to third embodiments can perform an A/D conversion process at high resolution without increasing power consumption. Therefore, by applying the analog-to-digital converter 1 to the image sensor 50 having a plurality of built-in analog-to-digital converters 1a as shown in FIG. 10, the features of high resolution and low power consumption can be more fully utilized.

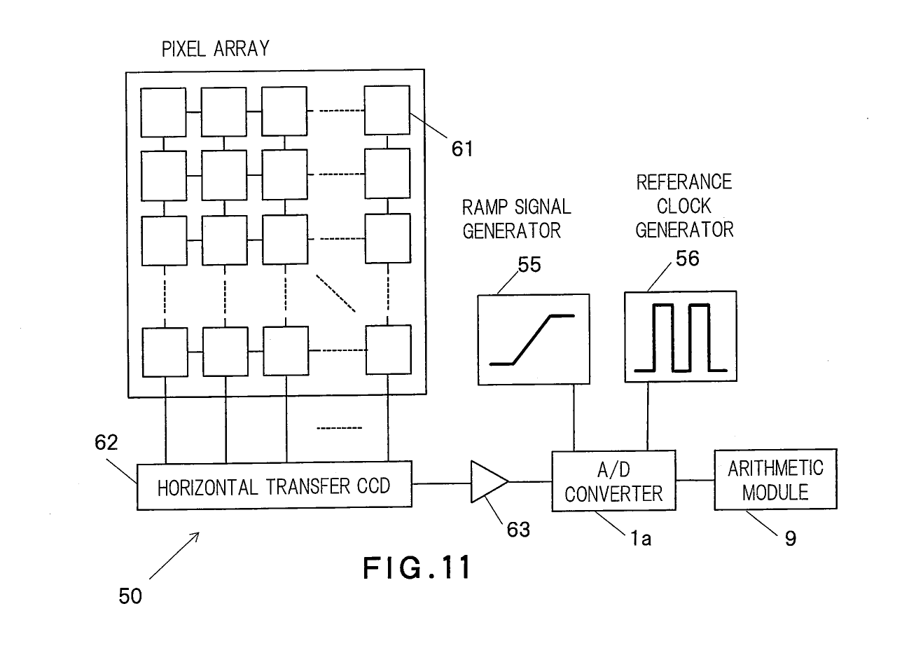

FIG. 10 shows an example of a CMOS sensor. However, the image sensor 50 in this embodiment is also applicable to CCDs (Charge Coupled Devices). FIG. 11 is a plan view of an image sensor 50 having built-in CCDs. The image sensor 50 of FIG. 11 has a pixel array 61 of vertical transfer CCDs, a horizontal transfer CCD 62, a charge-to-voltage converter 63, an A/D converter 1a, a ramp signal generator 55, a reference clock generator 56, and an arithmetic module 9.

The pixel array 61 has a photoelectric conversion module and transfer gate each provided per pixel, and vertical transfer CCDs provided per column.

In the image sensor 50 of FIG. 10, electric signals obtained by photoelectric conversion at a plurality of photoelectric conversion modules in each row pass through the vertical transfer CCDs and are transferred to the horizontal transfer CCD 62. Thereafter, the electric signals are sequentially transferred through the horizontal transfer CCD 62 and subjected to A/D conversion by the A/D converter 1a, after converted into voltage signals by the charge-to-voltage converter 63.

The image sensor 50 of FIG. 10, that is a CMOS sensor, requires a plurality of A/D converters 1a. By contrast, the image sensor 50 of FIG. 11 having CCDs requires only one A/D converter 1a due to a sequential A/D conversion process.

As described above, in the fourth embodiment, the image sensor 50 is configured with a plurality of A/D converters 1a which increase the resolution for a low level input signal, hence image pickup performance in dark places is improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An analog-to-digital converter comprising:
a comparator to compare, within a predetermined period, an input signal with a ramp signal whose signal level monotonically increases or monotonically decreases with time, or with a triangle wave signal that alternately repeats monotonic increase and monotonic decrease with time;
a first counter to count up or down in accordance with a logic of a signal that indicates a comparison result of the comparator within the predetermined period;
a count value storage to sequentially store count values of the first counter whenever the logic of the signal that indicates a comparison result of the comparator changes within the predetermined period;
a second counter to count the number of times the logic of the signal that indicates a comparison result of the comparator changes; and
an arithmetic module to output a value obtained by adding up the count values stored in the count value storage and dividing the added-up value by a count value of the second counter, as an analog-to-digital conversion value of the input signal.

2. The converter of claim 1, the ramp signal has a signal level that monotonically decreases with time, wherein the second counter increases the count value as the input signal has a lower signal level.

3. The converter of claim 1 further comprising a reference signal generator that generates the ramp signal and the triangle wave signal.

4. The converter of claim 3, wherein the reference signal generator comprises:
a reference voltage selector to select a first reference voltage or a second reference voltage based on the signal that indicates a comparison result of the comparator; and
an integrator to generate the ramp signal or the triangle wave signal by monotonically increasing or monotonically decreasing a reference voltage selected by the reference voltage selector.

5. The converter of claim 3, wherein
the comparator comprises:
a first input terminal to which the input signal is input; and
a second input terminal to which the ramp signal or the triangle wave signal is input, and
the reference signal generator comprises:
a capacitor connected between the second input terminal and a reference voltage node;
a first switch to be switched to electrically connect the second input terminal and the reference voltage node or not;
a second switch to be switched to charge the capacitor or not; and
a third switch to be switched to discharge the capacitor or not,
wherein the first to third switches are switched by the signal that indicates a comparison result of the comparator.

6. The converter of claim 1 further comprising a reference signal generator to generate the triangle wave signal by using the ramp signal input from outside the analog-to-digital converter.

7. The converter of claim 6, wherein
the comparator comprises:
a first input terminal to which the input signal is input; and
a second input terminal to which the ramp signal or the triangle wave signal is input, and
the reference signal generator comprises:
a capacitor connected between the second input terminal and a reference voltage node;
a first switch to be switched to input the ramp signal to the second input terminal or not;
a second switch to be switched to charge the capacitor or not; and
a third switch to be switched to discharge the capacitor or not,
wherein the first to third switches are switched by the signal that indicates a comparison result of the comparator.

8. The converter of claim 1 further comprising a signal synthesizer to select either of the ramp signal and the triangle wave signal input from outside the analog-to-digital converter, based on the signal that indicates a comparison result of the comparator.

9. The converter of claim 8, wherein
the comparator comprises:
a first input terminal to which the input signal is input; and
a second input terminal to which the ramp signal or the triangle wave signal is input, and
the reference signal generator comprises:
a first switch to be switched to input the ramp signal to second input terminal or not;
a capacitor having one end connected to the second input terminal;
a second switch to be switched to input the triangle wave signal to the other end of the capacitor or set the other end of the capacitor to a reference voltage,
wherein the first and second switches are switched by the signal that indicates a comparison result of the comparator.

10. The converter of claim 1 further comprising a plurality of analog-to-digital conversion modules,
wherein each analog-to-digital conversion module comprises the comparator, the first counter, the count value storage, and the second counter, and
the analog-to-digital conversion modules share the arithmetic module.

11. An image sensor comprising:
a photoelectric conversion module to perform photoelectric conversion to generate electric signals; and
an analog-to-digital converter to generate a digital signal in accordance with the electric signals, using the electric signals as the input signal,
wherein the analog-to-digital converter comprises:
a comparator to compare, within a predetermined period, an input signal with a ramp signal whose signal level monotonically increases or monotonically decreases with time, or with a triangle wave signal that alternately repeats monotonic increase and monotonic decrease with time;
a first counter to count up or down in accordance with a logic of a signal that indicates a comparison result of the comparator within the predetermined period;
a count value storage to sequentially store count values of the first counter whenever the logic of the signal that indicates a comparison result of the comparator changes within the predetermined period;
a second counter to count the number of times the logic of the signal that indicates a comparison result of the comparator changes; and
an arithmetic module to output a value obtained by adding up the count values stored in the count value storage and dividing the added-up value by a count value of the second counter, as an analog-to-digital conversion value of the input signal.

12. The image sensor according to claim 11 comprising:
a plurality of photoelectric conversion modules each corresponding to the photoelectric conversion module, an m (m being an integer of 1 or more) number of the photoelectric conversion modules being arranged in a first direction and an n (m being an integer of 1 or more) number of the photoelectric conversion modules being arranged in a second direction,
wherein the m number of analog-to-digital converters each corresponding to the analog-to-digital converter are provided corresponding to the m number of the photoelectric conversion modules arranged in the first direction.

13. The image sensor according to claim 11 comprising:
a plurality of photoelectric conversion modules each corresponding to the photoelectric conversion module, an m (m being an integer of 1 or more) number of the photoelectric conversion modules being arranged in a first direction and an n (m being an integer of 1 or more) number of the photoelectric conversion modules being arranged in a second direction;
a first transfer module to sequentially transfer the electric signals in the second direction; and
a second transfer module to sequentially transfer the electric signals transferred by the first transfer module, in the first direction,
wherein the analog-to-digital converter sequentially converts the electric signals transferred by the second transfer module by analog-to-digital conversion.

14. The image sensor of claim 11, the ramp signal has a signal level that monotonically decreases with time, wherein the second counter increases the count value as the input signal has a lower signal level.

15. The image sensor of claim 11 further comprising a reference signal generator that generates the ramp signal and the triangle wave signal.

16. The image sensor of claim 15, wherein the reference signal generator comprises:
a reference voltage selector to select a first reference voltage or a second reference voltage based on the signal that indicates a comparison result of the comparator; and
an integrator to generate the ramp signal or the triangle wave signal by monotonically increasing or monotonically decreasing a reference voltage selected by the reference voltage selector.

17. The image sensor of claim 15, wherein
the comparator comprises:
a first input terminal to which the input signal is input; and
a second input terminal to which the ramp signal or the triangle wave signal is input, and
the reference signal generator comprises:
a capacitor connected between the second input terminal and a reference voltage node;
a first switch to be switched to electrically connect the second input terminal and the reference voltage node or not;
a second switch to be switched to charge the capacitor or not; and
a third switch to be switched to discharge the capacitor or not,
wherein the first to third switches are switched by the signal that indicates a comparison result of the comparator.

18. The image sensor of claim 11 further comprising a reference signal generator to generate the triangle wave signal by using the ramp signal input from outside the analog-to-digital converter.

19. The image sensor of claim 18, wherein
the comparator comprises:
a first input terminal to which the input signal is input; and
a second input terminal to which the ramp signal or the triangle wave signal is input, and
the reference signal generator comprises:
a capacitor connected between the second input terminal and a reference voltage node;
a first switch to be switched to input the ramp signal to the second input terminal or not;
a second switch to be switched to charge the capacitor or not; and
a third switch to be switched to discharge the capacitor or not,
wherein the first to third switches are switched by the signal that indicates a comparison result of the comparator.

20. The image sensor of claim 11 further comprising a signal synthesizer to select either of the ramp signal and the triangle wave signal input from outside the analog-to-digital converter, based on the signal that indicates a comparison result of the comparator.
